(19) United States
(12) Patent Application Publication
(10) Pub. No.: US 2013/0040246 A1
(43) Pub. Date: Feb. 14, 2013

(54) MULTIPLE CHEMICAL TREATMENT PROCESS FOR REDUCING PATTERN DEFECT

(71) Applicant: Shinichiro KAWAKAMI, Watervliet, NY (US)

(72) Inventor: Shinichiro KAWAKAMI, Watervliet, NY (US)

(73) Assignee: TOKYO ELECTRON LIMITED, Tokyo (JP)

(21) Appl. No.: 13/206,441

(22) Filed: Aug. 9, 2011

(51) Int. Cl. G03F 7/40; B05C 13/00; B05C 9/08

(52) U.S. Cl. 430/325; 118/75

(57) ABSTRACT

A method and system for patterning a substrate with reduced defectivity is described. Once a pattern is formed in a layer of radiation-sensitive material using lithographic techniques, the substrate is rinsed to remove residual developing solution and/or other material. Thereafter, a first chemical treatment is performed using a first chemical solution, and a second chemical treatment is performed using a second chemical solution, wherein the second chemical solution has a different chemical composition than the first chemical solution. In one embodiment, the first chemical solution is selected to reduce pattern collapse, and the second chemical solution is selected to reduce pattern deformity, such as line edge roughness (LER) and/or line width roughness (LWR).

### BACKGROUND OF THE INVENTION

1. Field of Invention

The invention relates to a method and system for patterning a substrate, and more particularly to a method and system for preparing a pattern in a layer on a substrate.

2. Description of Related Art

In material processing methodologies, pattern etching comprises the application of a layer of radiation-sensitive material, such as photo-resist, to an upper surface of a substrate, the formation of a pattern in the layer of radiation-sensitive material using lithography, and the transfer of the pattern formed in the layer of radiation-sensitive material to an underlying thin film on the substrate using an etching process. The patterning of the radiation-sensitive material generally involves exposure of the radiation-sensitive material to a pattern of electromagnetic (EM) radiation using, for example, a lithography system, followed by the removal of the irradiated regions of the radiation-sensitive material (as in the case of positive tone resist), or non-irradiated regions (as in the case of negative tone resist) using a developing solution.

As the critical dimension (CD) decreases and the aspect ratio of the patterns formed in a layer of radiation-sensitive material increases, the potential for pattern defects including, but not limited to, pattern collapse, line edge roughness (LER), and line width roughness (LWR), becomes increasingly enhanced. In most situations, excessive pattern defects are unacceptable and, in some instances, catastrophic.

### SUMMARY OF THE INVENTION

The invention relates to a method and system for preparing a pattern in a layer on a substrate, and more particularly to a method and system for preparing a pattern formed in a layer on a substrate having reduced pattern defectivity. The invention further relates to a method and system for treating a pattern formed in a layer on a substrate to reduce pattern collapse and pattern deformities, such as line edge roughness (LER) and line width roughness (LWR).

According to one embodiment, a method for patterning a substrate is described. The method includes forming a layer of radiation-sensitive material on the substrate, exposing the layer of radiation-sensitive material to electromagnetic (EM) radiation according to an image pattern, and developing the layer of radiation-sensitive material to form a pattern therein from the image pattern. The method further includes rinsing the substrate with a rinse solution, performing a first chemical treatment following the rinsing, wherein the first chemical treatment includes a first chemical solution, and performing a second chemical treatment following the rinsing, wherein the second chemical treatment includes a second chemical solution, the second chemical solution having a different chemical composition than the first chemical solution.

According to another embodiment, a system for patterning a substrate is described. The system includes a substrate table for supporting and rotating a substrate mounted thereon, a rinse solution supply nozzle for dispensing a rinse solution onto the substrate, and a rinse solution supply system for supplying the rinse solution to the first nozzle. The system further includes a first chemical treatment solution supply nozzle for dispensing a first chemical solution onto the substrate, a first chemical treatment solution supply system for supplying the first chemical solution to the first chemical treatment solution supply nozzle, a second chemical treatment solution supply nozzle for dispensing a second chemical solution onto the substrate, and a second chemical solution supply system for supplying the second chemical solution to the second chemical treatment solution supply nozzle.

According to yet another embodiment, a track system for patterning a substrate is described. The track system includes a coating module and a process module. The process module includes a substrate table for supporting and rotating a substrate mounted thereon, a rinse solution supply nozzle for dispensing a rinse solution onto the substrate, and a rinse solution supply system for supplying the rinse solution to the first nozzle. The process module further includes a first chemical treatment solution supply nozzle for dispensing a first chemical solution onto the substrate, a first chemical treatment solution supply system for supplying the first chemical solution to the first chemical treatment solution supply nozzle, a second chemical treatment solution supply nozzle for dispensing a second chemical solution onto the substrate, and a second chemical solution supply system for supplying the second chemical solution to the second chemical treatment solution supply nozzle.

### BRIEF DESCRIPTION OF THE DRAWINGS

In the accompanying drawings:

FIG. 1 illustrates a method of patterning a substrate according to an embodiment;

FIGS. 2A through 2C illustrate other methods of patterning a substrate according to additional embodiments;

FIGS. 3A and 3B provide exemplary data for a method of patterning a substrate;

FIGS. 4A through 4C provide additional exemplary data for a method of patterning a substrate;

FIGS. 5A and 5B provide a schematic illustration representative of a system for patterning a substrate according to an embodiment; and

FIG. 6 provides a schematic illustration representative of a system for patterning a substrate according to another embodiment.

### DETAILED DESCRIPTION OF SEVERAL EMBODIMENTS

A method and system for patterning a substrate is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” or variation thereof means that a particular feature, structure, material, or characteristic described in connection with the embodiment is included in at least one embodiment of the invention, but do not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Nonetheless, it should be appreciated that, contained within the description are features which, notwithstanding the inventive nature of the general concepts being explained, are also of an inventive nature.

“Substrate” as used herein generically refers to the object being processed in accordance with embodiments of the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

To increase productivity in lithographic patterning for semiconductor manufacturing, for example, a method and system are described to address some or all of the above-described circumstances. In particular, it is important to rinse the pattern in the substrate following pattern developing, and to dry the substrate without causing pattern collapse and pattern deformities having excessive variation in the pattern edge and/or width, and to reduce remaining precipitation-based defects.

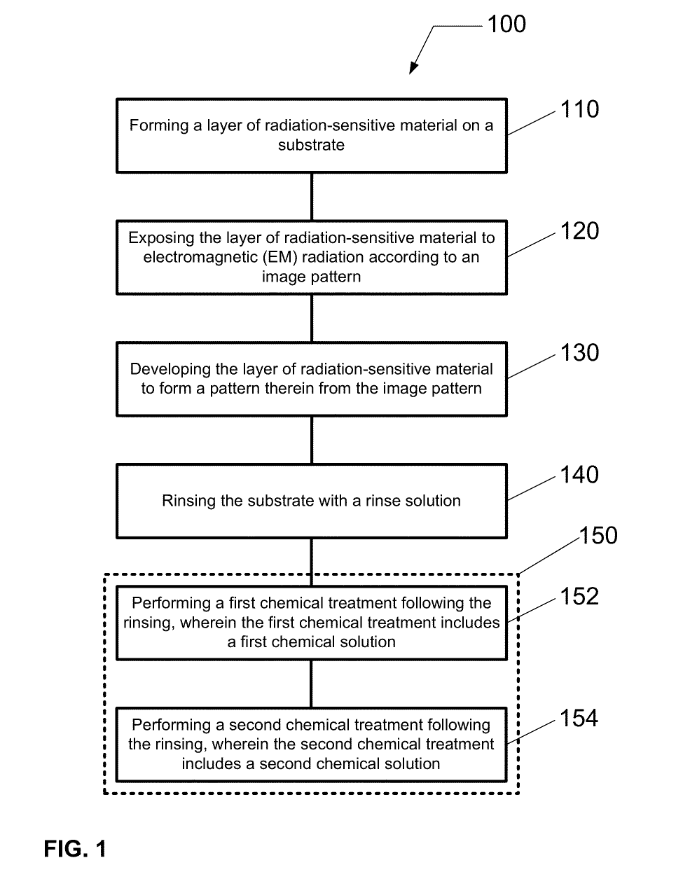

Referring now to the drawings, wherein like reference numerals designate identical or corresponding parts throughout the several views, FIG. 1 illustrates a method for patterning a substrate according to an embodiment. The method is illustrated in a flow chart 100, and begins in 110 with forming a layer of radiation-sensitive material on the substrate. The layer of radiation-sensitive material may include a photo-resist. For example, the layer of radiation-sensitive material may comprise a 248 nm (nanometer) resist, a 193 nm resist, a 157 nm resist, an EUV (extreme ultraviolet) resist, or an electron beam sensitive resist. Furthermore, for example, the layer of radiation-sensitive material may comprise a thermal freeze photo-resist, an electromagnetic (EM) radiation freeze photo-resist, or a chemical freeze photo-resist.

The layer of radiation-sensitive material may be formed by spin-coating the material onto the substrate. The layer of radiation-sensitive material may be formed using a track system. For example, the track system can comprise a Clean Track ACT® 8, ACT® 12, LITHIUS®, LITHIUS Pro™, or LITHIUS Pro V™ resist coating and developing system commercially available from Tokyo Electron Limited (TEL). Other systems and methods for forming a photo-resist film on a substrate are well known to those skilled in the art of spin-on resist technology. The coating process may be followed by one or more post-application bakes (PAB) to heat the substrate and one or more cooling cycles to cool the substrate following the one or more PABs.

In 120, the layer of radiation-sensitive material is exposed to electromagnetic (EM) radiation according to an image pattern. The radiation exposure system may include a dry or wet photo-lithography system. The image pattern may be formed using any suitable conventional stepping lithography system, or scanning lithography system. For example, the photo-lithography system is commercially available from ASML Netherlands B.V. (De Run 6501, 5504 DR Veldhoven, The Netherlands), or Canon USA, Inc., Semiconductor Equipment Division (3300 North First Street, San Jose, Calif. 95134). Alternatively, the image pattern may be formed using an electron beam lithography system.

In 130, the layer of radiation-sensitive material is developed to form a pattern therein from the image pattern. The pattern may be characterized by a nominal critical dimension (CD), a nominal line edge roughness (LER), and/or a nominal line width roughness (LWR). The pattern may include a line pattern. The developing process can include exposing the substrate to a developing solution in a developing system, such as a track system. For example, the developing solution may include tetramethyl ammonium hydroxide (TMAH). Alternatively, for example, the developing solution may include other alkaline solutions, such as a sodium hydroxide solution, a potassium hydroxide solution, etc. Additionally, for example, the track system can comprise a Clean Track ACT® 8, ACT® 12, LITHIUS®, LITHIUS Pro™, or LITHIUS Pro V™ resist coating and developing system commercially available from Tokyo Electron Limited (TEL). The developing process may be preceded by one or more post-exposure bakes (PEB) to heat the substrate and one or more cooling cycles to cool the substrate following the one or more PEBs.

In 140, the substrate is rinsed with a rinse solution. The rinse solution may include water, such as deionized (DI) water, or an aqueous solution containing a surfactant dissolved in water. The rinse solution may be used to displace and/or remove residual developing solution from the substrate. Preferably, the rinse solution contains only water. When the rinse solution contains only water (without surfactant), variations in the nominal CD may be prevented or minimized. After the developing process, the presence of developing solution on the pattern causes swelling of the pattern and increased permeability. As a result, when the rinse solution contains a surfactant, the rinse solution permeates into the pattern more freely, thus, causing variations in the nominal CD. In other words, rinsing the pattern on the substrate with only water, performed prior to additional chemical treatment, replaces the developing solution on the substrate with water and washes away the developing solution, thus, restraining variation in the nominal CD.

In 150, multiple chemical treatments are performed following the rinsing of the substrate to reduce and/or improve pattern collapse and pattern deformities, such as line edge roughness (LER) and line width roughness (LWR).

During the performing of the multiple chemical treatments, in 152, a first chemical treatment is performed following the rinsing, wherein the first chemical treatment includes a first chemical solution. The first chemical solution may include a first surfactant solution. The first chemical solution may include an anionic, a nonionic, a cationic, and/or amphoteric surfactant. Suitable anionic surfactants include sulfonates, sulfates, carboxylates, phosphates, and mixtures thereof. Suitable cationic surfactants may include: alkali metals, such as sodium or potassium; alkaline earth metals, such as calcium or magnesium; ammonium; or substituted ammonium compounds, including mono-, di- or tri-ethanolammonium cation compounds; or mixtures thereof.

As an example, the first chemical solution may include an aqueous solution containing a polyethylene glycol-based or acetylene glycol-based surfactant having a molecular weight of 1600 or less and a carbon number of its hydrophobic group of 10 or greater. It may be desirable that the hydrophobic group of the surfactant is not double-bonded or triple-bonded.

As another example, the first chemical composition may include one or more surfactant solutions selected from the FIRM™ family of surfactants (e.g., FIRM™-A, FIRM™-B, FIRM™-C, FIRM™-D, FIRM™ Extreme 10, etc.) co-developed by Tokyo Electron Limited (TEL) and Clariant (Japan) KK (Bunkyo-ku, Tokyo, Japan) (a subsidiary of Swiss manufacturer Clariant).

As another example, the first chemical composition may include a mixture of an amine compound and a surfactant.

As yet another example, the first chemical composition for the first chemical solution may be selected to reduce pattern collapse.

In 154, a second chemical treatment is performed following the rinsing, wherein the second chemical treatment includes a second chemical solution. The second chemical solution has a different chemical composition than the first chemical solution. In other words, the second chemical solution has a different elemental composition, i.e., atomic and/or molecular composition, than the first chemical solution.

The second chemical solution may include a second surfactant solution. The second chemical solution may include an anionic, a nonionic, a cationic, and/or amphoteric surfactant. Suitable anionic surfactants include sulfonates, sulfates, carboxylates, phosphates, and mixtures thereof. Suitable cationic surfactants may include: alkali metals, such as sodium or potassium; alkaline earth metals, such as calcium or magnesium; ammonium; or substituted ammonium compounds, including mono-, di- or tri-ethanolammonium cation compounds; or mixtures thereof.

As an example, the second chemical solution may include an aqueous solution containing a polyethylene glycol-based or acetylene glycol-based surfactant having a molecular weight of 1600 or less and a carbon number of its hydrophobic group of 10 or greater. It may be desirable that the hydrophobic group of the surfactant is not double-bonded or triple-bonded.

As another example, the second chemical composition may include one or more surfactants selected from the FIRM™ family of surfactants (e.g., FIRM™-A, FIRM™-B, FIRM™-C, FIRM™-D, FIRM™ Extreme 10, etc.) co-developed by Tokyo Electron Limited (TEL) and Clariant (Japan) KK (Bunkyo-ku, Tokyo, Japan) (a subsidiary of Swiss manufacturer Clariant).

As another example, the first chemical composition may include a mixture of an amine compound and a surfactant.

As yet another example, the second chemical composition for the second chemical solution may be selected to reduce pattern deformities, such as line edge roughness (LER) and/or line width roughness (LWR).

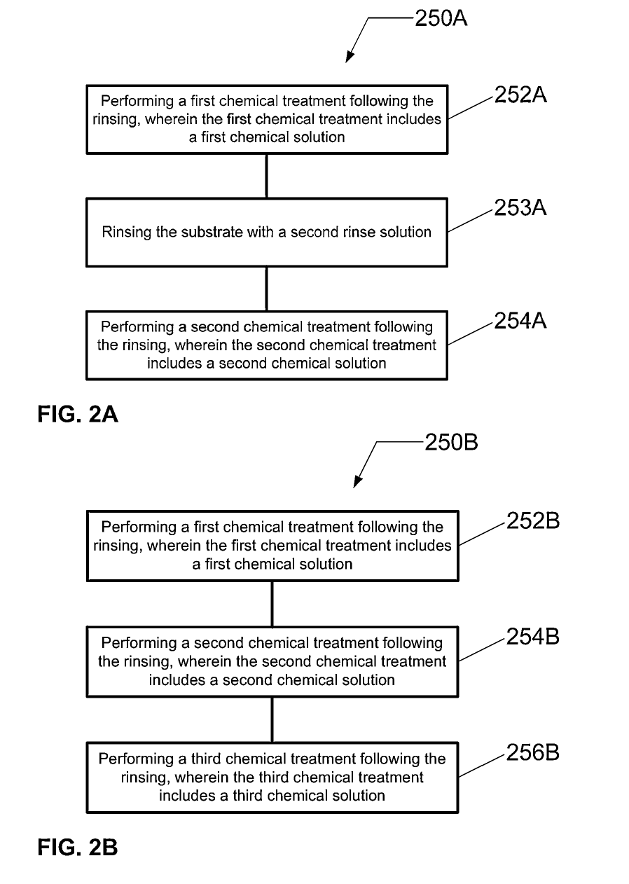

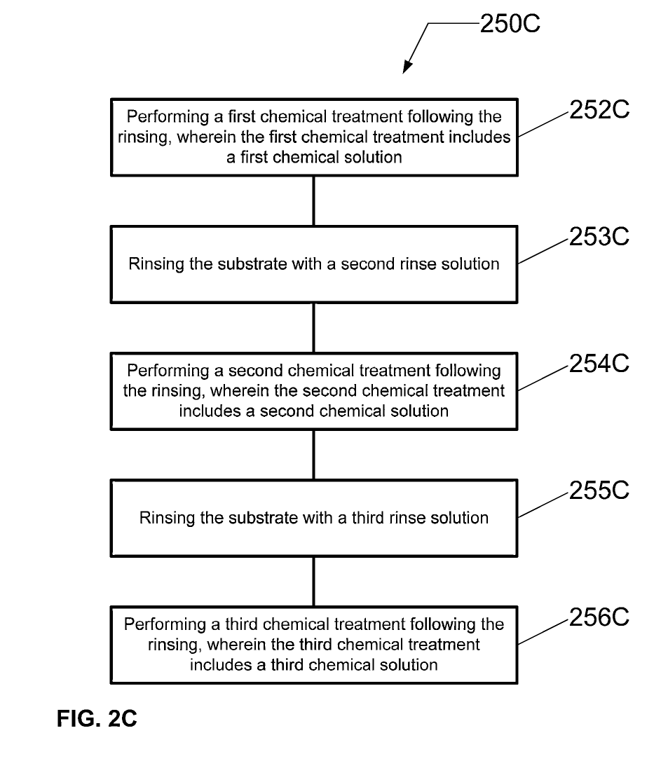

Referring now to FIGS. 2A through 2C, methods for patterning a substrate according to additional embodiments are provided. As illustrated in FIG. 2A, a method for performing multiple chemical treatments is provided in a flow chart 250A beginning in 252A with performing a first chemical treatment following the rinsing of the substrate. The first chemical treatment, as described above, may include treatment with a first chemical solution.

Then, in 253A, the substrate is rinsed with a second rinse solution. The second rinse solution may include water, such as deionized (DI) water, or an aqueous solution containing a surfactant dissolved in water.

Thereafter, in 254A, a second chemical treatment is performed following the rinsing of the substrate with the rinse solution and the rinsing of the substrate with the second rinse solution. As described above, the second chemical treatment includes a treatment with a second chemical solution.

As illustrated in FIG. 2B, a method for performing multiple chemical treatments is provided in a flow chart 250B beginning in 252B with performing a first chemical treatment following the rinsing of the substrate. The first chemical treatment, as described above, may include treatment with a first chemical solution.

Then, in 254B, a second chemical treatment is performed following the rinsing of the substrate with the rinse solution. As described above, the second chemical treatment includes treatment with a second chemical solution.

Thereafter, in 256B, a third chemical treatment is performed following the rinsing of the substrate with the rinse solution. The third chemical treatment includes treatment with a third chemical solution.

As illustrated in FIG. 2C, a method for performing multiple chemical treatments is provided in a flow chart 250C beginning in 252C with performing a first chemical treatment following the rinsing of the substrate. The first chemical treatment, as described above, may include treatment with a first chemical solution.

In 253C, the substrate is rinsed with a second rinse solution. The second rinse solution may include water, such as deionized (DI) water, or an aqueous solution containing a surfactant dissolved in water.

Then, in 254C, a second chemical treatment is performed following the rinsing of the substrate with the rinse solution. As described above, the second chemical treatment includes treatment with a second chemical solution.

In 255C, the substrate is rinsed with a third rinse solution. The third rinse solution may include water, such as deionized (DI) water, or an aqueous solution containing a surfactant dissolved in water.

Thereafter, in 256C, a third chemical treatment is performed following the rinsing of the substrate with the rinse solution. The third chemical treatment includes treatment with a third chemical solution.

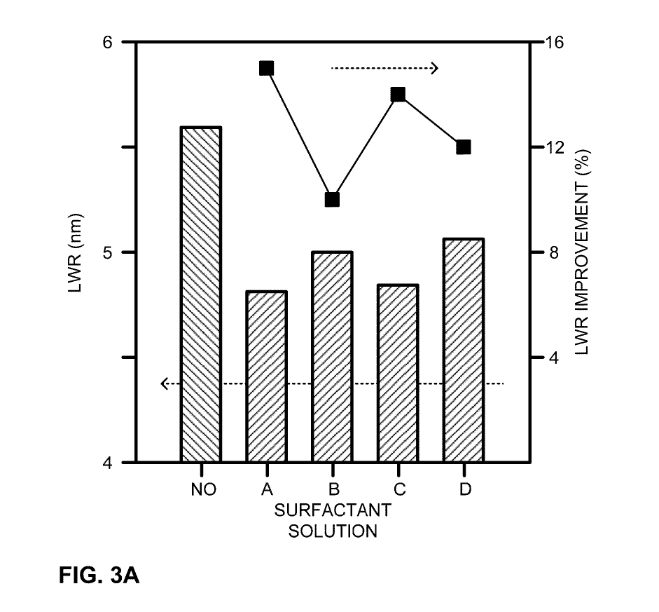

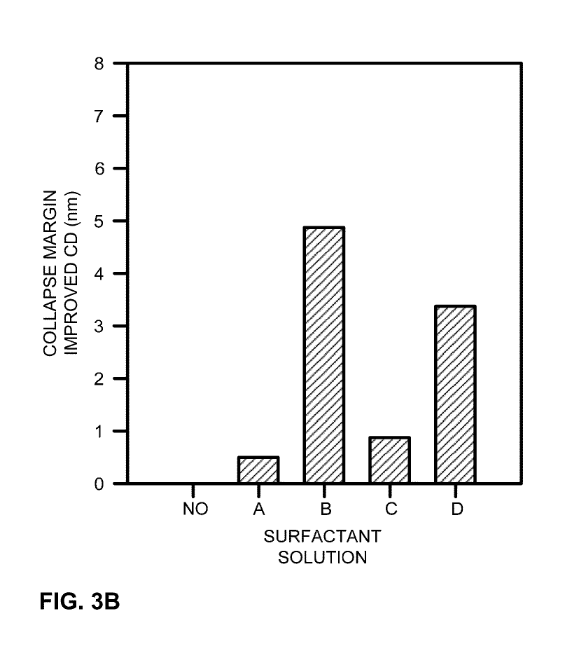

As shown in FIGS. 3A and 3B, exemplary data is provided for performing a method of patterning a substrate according to embodiments described above. In FIG. 3A, the line width roughness (LWR) for a pattern on a substrate, measured in nanometers (nm), is presented as a bar chart for the following: (1) a reference case wherein no chemical treatment of the pattern was performed following the developing and rinsing of the pattern (labeled as “NO” surfactant solution in FIG. 3A); and (2) several comparative cases wherein a chemical treatment of the pattern were performed following the developing and rinsing of the pattern (labeled as “A”, “B”, “C”, and “D” surfactant solutions in FIG. 3A). In the latter, the chemical treatment of the pattern used the following chemical solutions: (i) FIRM™-A (labeled as “A”); (ii) FIRM™-B (labeled as “B”); (iii) FIRM™-C (labeled as “C”); and (iv) FIRM™-D (labeled as “D”).

Inspection of FIG. 3A indicates that the nominal LWR for the reference case, which provides a reference value of the LWR, is slightly greater than 5.5 nm. Further, when the pattern is chemically treated with FIRM™-A (labeled as “A”) or FIRM™-C, the improvement to the LWR exceeds 10%, and even about 14% (measured as a ratio of the difference between the chemically treated LWR and the nominal LWR to the nominal LWR (×100%)). Further yet, the improvement to the LWR ranges from about 14% to about 16%. Herein, the inventor has discovered that each chemical treatment solution performs differently, and some outperform others.

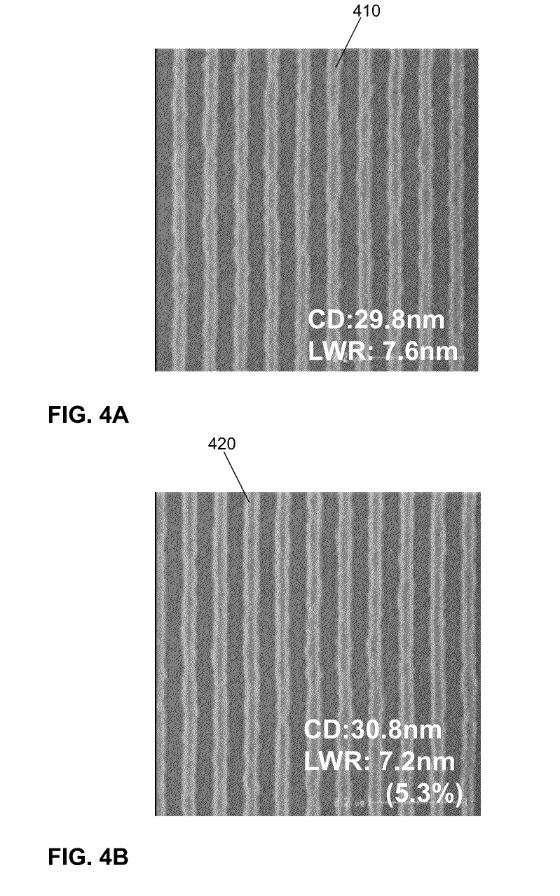

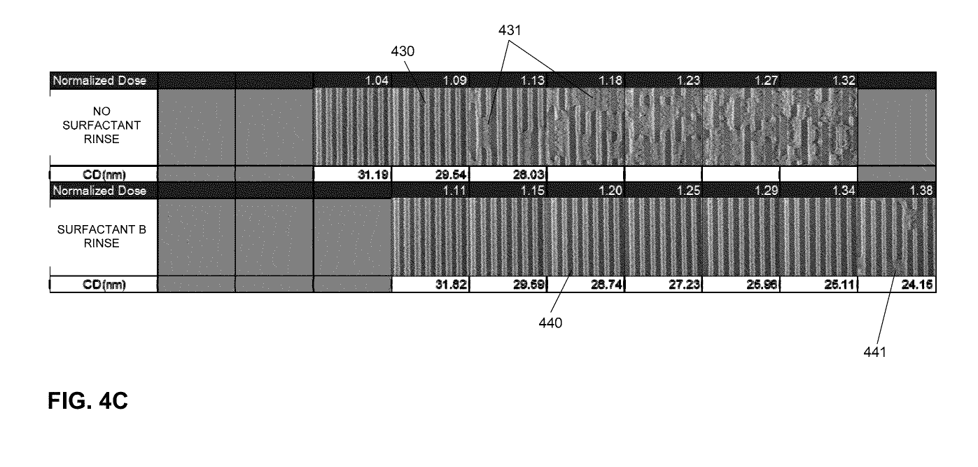

As an example, FIG. 4A provides a SEM (scanning electron microscope) image illustrating a reduction in the LWR of a line pattern. As shown in FIG. 4A, a line pattern 410 was prepared without any chemical treatment following developing and rinsing of the line pattern. The nominal CD was 29.8 nm with a nominal LWR of about 7.6 nm. As shown in FIG. 4B, when line pattern 410 was chemically treated with FIRM™-A, a new line pattern 420 was produced with a CD of 30.8 nm and an LWR of 7.2 nm (e.g., a 5.3% reduction of the LWR relative to the nominal LWR).

In FIG. 3B, the collapse margin improved CD (critical dimension) for a pattern on a substrate, measured in nanometers (nm), is presented as a bar chart for the following: (1) a reference case wherein no chemical treatment of the pattern was performed following the developing and rinsing of the pattern (labeled as “NO” surfactant solution in FIG. 3B); and (2) several comparative cases wherein a chemical treatment of the pattern was performed following the developing and rinsing of the pattern (labeled as “A”, “B”, “C”, and “D” surfactant solutions in FIG. 3B). In the latter, the chemical treatment of the pattern used the following chemical solutions: (i) FIRM™-A (labeled as “A”); (ii) FIRM™-B (labeled as “B”); (iii) FIRM™-C (labeled as “C”); and (iv) FIRM™-D (labeled as “D”).

The collapse margin improved CD is measured as a difference between a minimum printable CD achieved without performing any chemical treatment (i.e., the nominal CD for the pattern) and a minimum printable CD achieved when performing the chemical treatment. Therefore, inspection of FIG. 3B indicates that the nominal collapse margin for the reference case is set at 0 nm. Further, when the pattern is chemically treated with one of the chemical solutions, the collapse margin is improved. Relatively speaking, FIRM™-B (labeled as “B”) outperforms the other chemical treatments, and exhibits an improvement of the collapse margin that exceeds about 4 nm, and even about 4.5 nm. Herein, the inventor has discovered that each chemical treatment solution performs differently, and some outperform others. Moreover, the inventor has discovered that different chemical treatments may be used to address different pattern defects, e.g., a first chemical treatment to address pattern collapse and a second chemical treatment to address pattern deformities.

As an example, FIG. 4C provides a SEM image illustrating an improvement to the collapse margin of a line pattern. As shown in FIG. 4C, a reference line pattern 430 was prepared without any chemical treatment following developing and rinsing of the pattern. Using a normalized dose of about 1.09 for imaging the pattern, reference line pattern 430 has a minimum printable CD of about 29.54 nm. As the normalized dose was increased to about 1.13, the CD decreases to about 28.03 nm; however, pattern collapse 431 was observed. Furthermore, as shown in FIG. 4C, an improved line pattern 440 was prepared with chemical treatment following developing and rinsing of the pattern. Therein, improved line pattern 440 was chemically treated with FIRM™-B. Using a normalized dose of about 1.34 for imaging the pattern, improved line pattern 440 has a minimum printable CD of about 25.11 nm. As the normalized dose was increased to about 1.38, the CD decreases to about 24.15 nm; however, pattern collapse 441 was observed. The collapse margin improved CD is about 4.43 nm.

As another example, a line pattern was prepared in a first EUV resist without any chemical treatment following developing and rinsing of the line pattern. The nominal CD for a first exposure condition was 28.5 nm with a nominal LWR of about 6.2 nm. When the line pattern was chemically treated with FIRM™ Extreme 10, a new line pattern was produced with a CD of 30.6 nm and an LWR of 6.0 nm. Furthermore, treatment of the line pattern with FIRM™ Extreme 10 following other exposure conditions resulted in improvement to the collapse margin, measured as a collapse margin improved CD of about 4 nm.

As yet another example, a line pattern was prepared in a second EUV resist without any chemical treatment following developing and rinsing of the line pattern. The nominal CD for a first exposure condition was 26.4 nm with a nominal LWR of about 4.2 nm. When the line pattern was chemically treated with FIRM™ Extreme 10, a new line pattern was produced with a CD of 27.7 nm and an LWR of 3.7 nm. Furthermore, treatment of the line pattern with FIRM™ Extreme 10 following other exposure conditions resulted in improvement to the collapse margin, measured as a collapse margin improved CD of about 6 nm.

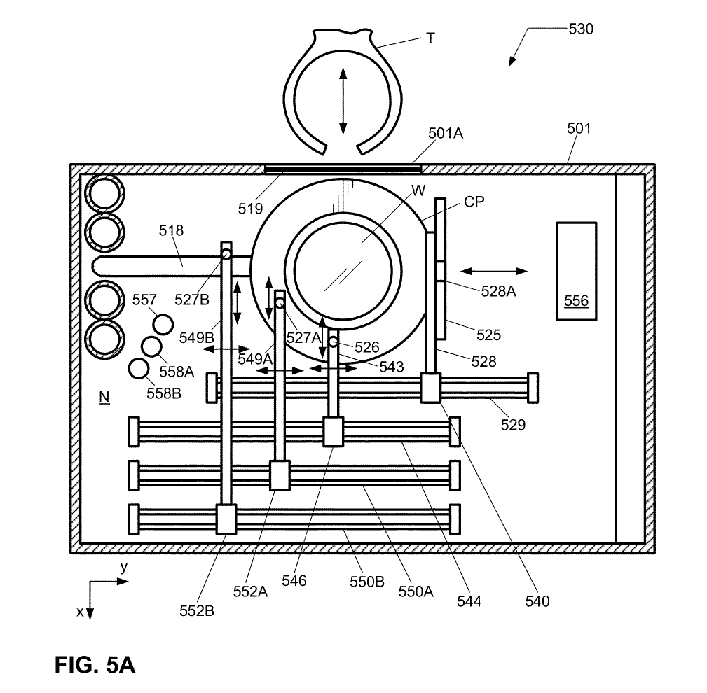

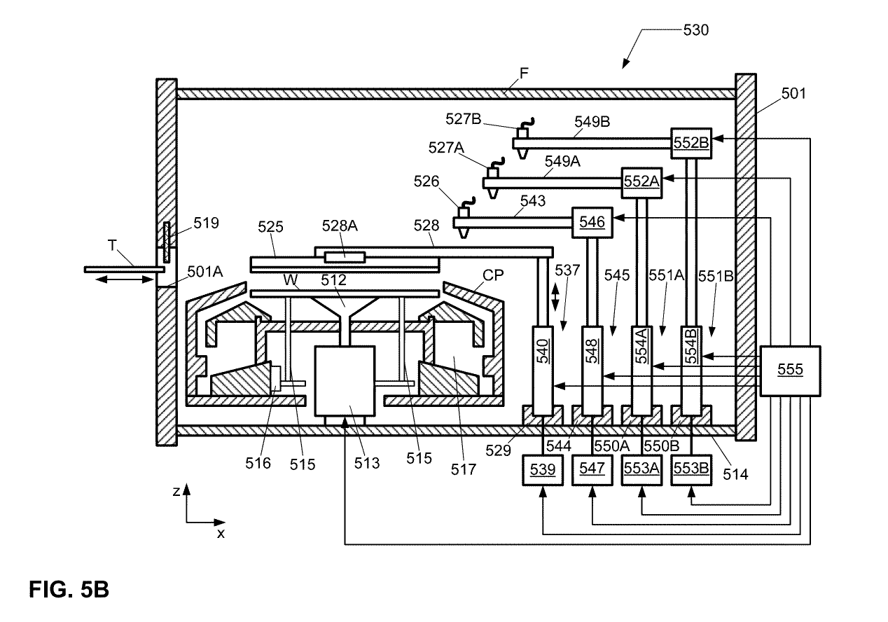

Referring now to FIGS. 5A and 5B, a system for patterning a substrate is described according to an embodiment. FIG. 5A is a plan view of a system 530 for rinsing and chemically treating a pattern on a substrate, and FIG. 5B is a cross-sectional view thereof. System 530 is, among other things, capable of performing the aforementioned methods for patterning a substrate. Further, system 530 may be included as a module in a coating and developing apparatus, such as the apparatus described in U.S. Patent Application Publication No. 2007/0072092, entitled “Rinse Treatment Method, Developing Treatment Method and Developing Apparatus”, and filed on Sep. 6, 2006. Moreover, system 530 may be included as a module in a track system, such as a Clean Track ACT® 8, ACT® 12, LITHIUS®, LITHIUS Pro™, or LITHIUS Pro V™ resist coating and developing system commercially available from Tokyo Electron Limited (TEL).

System 530 includes a housing 501, and a fan-filter unit F that is provided at a ceiling of housing 501 for producing a downward flow of clean air into housing 501. System 530 is provided with a circular cup CP that is located at approximately a central portion of housing 501, and a substrate table 512 disposed within circular cup CP. The substrate table 512 is configured to support and rotate a substrate W mounted thereon. As an example, the substrate table 512 may securely hold substrate W by vacuum suction. A rotary drive system 513 is coupled to the substrate table 512, and configured to rotate the substrate table 512. The rotary drive system 513 may be attached to a base plate 514 of housing 501.

Inside the circular cup CP, lift pins 515 are arranged to raise and lower substrate W to and from substrate table 512. The lift pins 515 may rise and lower by means of a drive mechanism 516, such as a pneumatic cylinder or the like. Additionally, inside the circular cup CP, a drain port 517 may be provided for draining excess fluid. A drain pipe 518 is coupled to the drain port 517, and the drain pipe 518 passes through a space N between the base plate 514 and the housing 501, as shown in FIG. 5A.

Through a side wall of housing 501, an opening 501A is formed to allow a substrate carrier arm T of an adjacent substrate carrier unit (not shown) to access an interior space of housing 501. The opening 501A may be opened and closed by means of a shutter 519. When the substrate W is carried into and out of housing 501, the shutter 519 is opened so that the substrate carrier arm T may enter housing 501. The substrate W may then be transferred between the substrate carrier arm T and the substrate table 512 with the raising and lowering of lift pins 515.

As shown in FIGS. 5A and 5B, a developing solution supply nozzle 525 for supplying a developing solution onto a front surface of substrate W is disposed above the circular cup CP. Additionally, a rinse solution supply nozzle 526 for supplying a rinse solution onto substrate W is disposed above circular cup CP. Furthermore, a first chemical treatment solution supply nozzle 527A for supplying a first chemical solution onto substrate W is disposed above circular cup CP. Further yet, a second chemical treatment solution supply nozzle 527B for supplying a second chemical solution onto substrate W is disposed above circular cup CP. The developing solution supply nozzle 525, the rinse solution supply nozzle, the first chemical treatment solution supply nozzle 527A, and the second chemical treatment solution supply nozzle 527B may be configured to be movable between a supply position above substrate W and a waiting/holding position outside substrate W.

The rinse solution may include deionized (DI) water, or solution containing a surfactant dissolved in water.

The developing solution supply nozzle 525 may be constructed in an elongated shape and arranged such that its longitudinal axis is kept horizontal. The developing solution supply nozzle 525 may have a plurality of discharge ports on a lower surface so that the developing solution may discharge from the developing solution supply nozzle 525 as a sheet of fluid. The developing solution supply nozzle 525 may be detachably attached to a tip portion of a developing solution nozzle scan arm 528 through use of a holding member 528a. The developing solution nozzle scan arm 528 is attached to an upper end portion of a developing solution nozzle vertical support member 537 extending in a vertical direction from a top of a developing solution nozzle guide rail 529 arranged along the y-direction on base plate 514.

The developing solution supply nozzle 525 is configured to horizontally move along the y-direction by means of a y-axis drive mechanism 539 together with developing solution nozzle vertical support member 537.

The developing solution nozzle vertical support member 537 can be raised and lowered by a z-axis drive mechanism 540 so that the developing solution supply nozzle 525 is moved between a discharge position proximate substrate W and a non-discharge position there above by raising and lowering the developing solution nozzle vertical support member 537.

When dispensing the developing solution on substrate W, the developing solution supply nozzle 525 is positioned above substrate W, and substrate W is rotated one-half turn or more, e.g., one or more turns while the developing solution supply nozzle 525 is dispensing the developing solution. Note that at the time when the developing solution is dispensed, the developing solution supply nozzle 525 may be scanned along the developing solution nozzle guide rail 529 without rotating substrate W.

The rinse solution supply nozzle 526 may be detachably attached to a tip portion of a rinse solution nozzle scan arm 543. A rinse solution nozzle guide rail 544 is arranged outside the developing solution nozzle guide rail 529 on base plate 514. The rinse solution nozzle scan arm 543 is attached to an upper end portion of a rinse solution nozzle vertical support member 545 extending in the vertical direction from a top of the rinse solution nozzle guide rail 544 via a rinse solution nozzle x-axis drive mechanism 546.

The rinse solution supply nozzle 526 is configured to horizontally move along the y-direction by means of a y-axis drive mechanism 547 together with the rinse solution nozzle vertical support member 545. Furthermore, the rinse solution nozzle vertical support member 545 can be raised or lowered to move the rinse solution supply nozzle 526 between a discharge position proximate substrate W and a non-discharge position there above. Further, the rinse solution nozzle scan arm 543 is provided movable along the x-direction by means of the rinse solution nozzle x-axis drive mechanism 546.

The first chemical treatment solution supply nozzle 527A may be detachably attached to a tip portion of a first chemical treatment solution nozzle scan arm 549A. A first chemical treatment solution nozzle guide rail 550A is arranged outside the rinse solution nozzle guide rail 544 on base plate 514. The first chemical treatment solution nozzle scan arm 549A is attached to an upper end portion of a first chemical treatment solution nozzle vertical support member 551A extending in the vertical direction from a top of the first chemical treatment solution nozzle guide rail 550A via a first chemical treatment solution nozzle x-axis drive mechanism 552A.

The first chemical treatment solution supply nozzle 527A is configured to horizontally move along the y-direction by means of a first chemical treatment solution nozzle y-axis drive mechanism 553A together with the first chemical treatment solution nozzle vertical support member 551A. Furthermore, the first chemical treatment solution nozzle vertical support member 551A can be raised or lowered to move the first chemical treatment solution supply nozzle 527A between a discharge position proximate substrate W and a non-discharge position there above. Further, the first chemical treatment solution nozzle scan arm 549A is provided movable along the x-direction by means of the first chemical treatment solution nozzle x-axis drive mechanism 552A.

The second chemical treatment solution supply nozzle 527B may be detachably attached to a tip portion of a second chemical treatment nozzle solution scan arm 549B. A second chemical treatment solution nozzle guide rail 550B is arranged outside the rinse solution nozzle guide rail 544B on base plate 514. The second chemical treatment solution nozzle scan arm 549B is attached to an upper end portion of a second chemical treatment solution nozzle vertical support member 551B extending in the vertical direction from a top of the second chemical treatment solution nozzle guide rail 550B via a second chemical treatment solution nozzle x-axis drive mechanism 552B.

The second chemical treatment solution supply nozzle 527B is configured to horizontally move along the y-direction by means of a second chemical treatment solution nozzle y-axis drive mechanism 553B together with the second chemical treatment solution nozzle vertical support member 551B. Furthermore, the second chemical treatment solution nozzle vertical support member 551B can be raised or lowered to move the second chemical treatment solution supply nozzle 527B between a discharge position proximate substrate W and a non-discharge position there above. Further, the second chemical treatment solution nozzle scan arm 549B is provided movable along the x-direction by means of the second chemical treatment solution nozzle x-axis drive mechanism 552B.

It should be noted that the y-axis drive mechanisms 539, 547, 553A, and 553B, the z-axis drive mechanisms 540, 548, 554A, and 554B, the x-axis drive mechanisms 546, 552A, and 552B, and the rotary drive system 513 are controlled by a drive controller 555. The rinse solution supply nozzle 526, the first chemical treatment solution supply nozzle 527A, and the second chemical treatment solution supply nozzle 527B may move relative to each other in the x- and y-directions.

Further, as shown in FIG. 5A, on the right side of the cup CP, a developing solution supply nozzle waiting unit 556 (a position where the developing solution supply nozzle 525 waits) may be provided in which a cleaning mechanism (not shown) may be employed for cleaning the developing solution supply nozzle 525. Further yet, on the left side of the cup CP, a rinse solution supply nozzle waiting unit 557, a first chemical treatment solution supply nozzle waiting unit 558A, and a second chemical treatment solution supply nozzle waiting unit 558B may be provided, respectively, in which cleaning mechanisms (not shown) may be employed for cleaning the respective nozzles.

Although not shown, system 530 may further include a third chemical treatment solution supply nozzle for dispensing a third chemical solution onto substrate W, and a third chemical solution supply system for supplying the third chemical solution to the third chemical treatment solution supply nozzle.

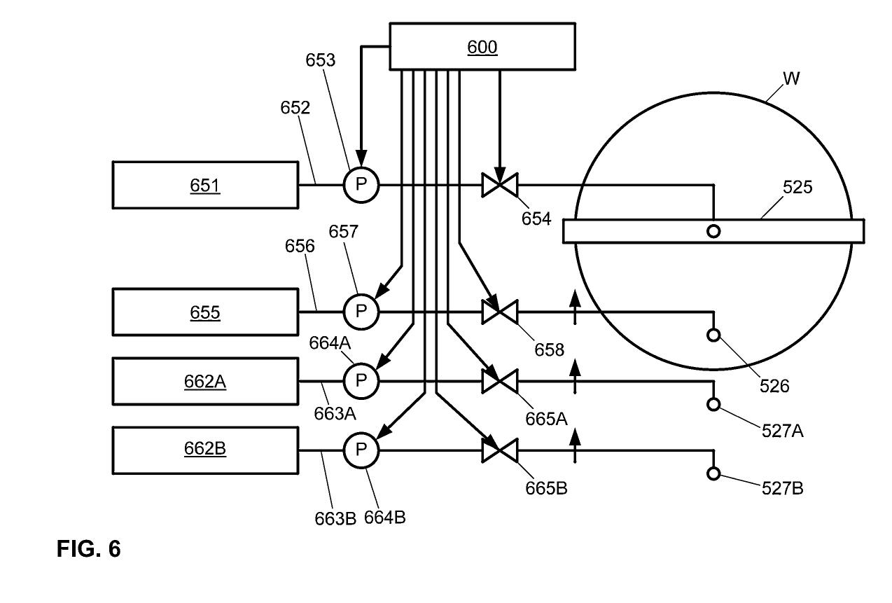

Referring now to FIG. 6, a schematic diagram of a treatment solution supply system is provided according to another embodiment. As shown in FIG. 6, the developing solution supply nozzle 525 is connected to a developing solution supply system 651 storing the developing solution via a developing solution supply pipe 652. Along the developing solution supply pipe 652, a developing solution supply pump 653 is disposed, wherein a developing solution supply valve 654 is located for supplying the developing solution.

Additionally, the rinse solution supply nozzle 526 is connected to a rinse solution supply system 655 storing the rinse solution via a rinse solution supply pipe 656. Along the rinse solution supply pipe 656, a rinse solution supply pump 657 is disposed, wherein a rinse solution supply valve 658 is located for supplying the rinse solution.

Furthermore, the first chemical treatment solution supply nozzle 527A is connected to a first chemical treatment solution supply system 662A storing the first chemical treatment solution via a first chemical treatment solution supply pipe 663A. Along the first chemical treatment solution supply pipe 663A, a first chemical treatment solution supply pump 664A is disposed, wherein a first chemical treatment solution supply valve 665A is located for supplying the first chemical treatment solution.

Further yet, the second chemical treatment solution supply nozzle 527B is connected to a second chemical treatment solution supply system 662B storing the second chemical treatment solution via a second chemical treatment solution supply pipe 663B. Along the second chemical treatment solution supply pipe 663B, a second chemical treatment solution supply pump 664B is disposed, wherein a second chemical treatment solution supply valve 665B is located for supplying the second chemical treatment solution.

The pumps 653, 657, 664A, and 664B and the valves 654, 658, 665A, and 665B are controlled by a supply control unit 600.

At least one process parameter for the first chemical treatment may be adjusted to improve the reduction of pattern collapse and/or pattern deformity. For example, the process parameter may include a rotation rate for the substrate, a dispensing rate for the first chemical solution, a concentration of a chemical constituent in the first chemical solution, etc.

Further, at least one process parameter for the second chemical treatment may be adjusted to improve the reduction of pattern collapse and/or pattern deformity. For example, the process parameter may include a rotation rate for the substrate, a dispensing rate for the second chemical solution, a concentration of a chemical constituent in the second chemical solution, etc.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for patterning a substrate, comprising:
forming a layer of radiation-sensitive material on said substrate;
exposing said layer of radiation-sensitive material to electromagnetic (EM) radiation according to an image pattern;
developing said layer of radiation-sensitive material to form a pattern therein from said image pattern;
rinsing said substrate with a rinse solution;
performing a first chemical treatment following said rinsing, wherein said first chemical treatment includes a first chemical solution; and
performing a second chemical treatment following said rinsing, wherein said second chemical treatment includes a second chemical solution, said second chemical solution having a different chemical composition than said first chemical solution.

2. The method of claim 1, wherein said rinse solution comprises deionized water.

3. The method of claim 1, wherein said first chemical solution contains a first surfactant solution.

4. The method of claim 3, wherein said second chemical solution contains a second surfactant solution different than said first surfactant solution.

5. The method of claim 1, further comprising:
selecting a first chemical composition for said first chemical solution to reduce pattern collapse.

6. The method of claim 5, further comprising:
selecting said first chemical composition to improve pattern collapse margin by 4 nm (nanometers), wherein said pattern collapse margin is measured as a difference between a minimum printable critical dimension (CD) without performing said first chemical treatment and a minimum printable critical dimension (CD) when performing said first chemical treatment.

7. The method of claim 1, further comprising:
selecting a second chemical composition for said second chemical solution to reduce line edge roughness (LER) and/or line width roughness (LWR).

8. The method of claim 7, further comprising:
selecting said second chemical solution to reduce LWR to a value less than 5 nm (nanometers).

9. The method of claim 7, further comprising:
selecting said second chemical composition to reduce LWR by an amount that exceeds 10% of a nominal LWR achieved without performing said second chemical treatment.

10. The method of claim 7, further comprising:
selecting said second chemical composition to reduce LWR by an amount that exceeds 14% of a nominal LWR achieved without performing said second chemical treatment.

11. The method of claim 1, further comprising:
rinsing said substrate with a second rinse solution following said performing said first chemical treatment and preceding said performing said second chemical treatment.

12. The method of claim 1, further comprising:
performing a third chemical treatment following said rinsing, wherein said third chemical treatment includes a third chemical solution, said third chemical solution having a different chemical composition than said first chemical solution and said second chemical solution.

13. The method of claim 12, further comprising:
rinsing said substrate with a second rinse solution following said performing said first chemical treatment and preceding said performing said second chemical treatment; and
rinsing said substrate with a third rinse solution following said performing said second chemical treatment and preceding said performing said third chemical treatment.

14. A system for patterning a substrate, comprising:
a substrate table for supporting a rotating a substrate mounted thereon;
a rinse solution supply nozzle for dispensing a rinse solution onto said substrate;
a rinse solution supply system for supplying said rinse solution to said rinse solution supply nozzle;
a first chemical treatment solution supply nozzle for dispensing a first chemical solution onto said substrate;
a first chemical treatment solution supply system for supplying said first chemical solution to said first chemical treatment solution supply nozzle;
a second chemical treatment solution supply nozzle for dispensing a second chemical solution onto said substrate; and
a second chemical treatment solution supply system for supplying said second chemical solution to said second chemical treatment solution supply nozzle.

15. The system of claim 14, further comprising:
a third chemical treatment solution supply nozzle for dispensing a third chemical solution onto said substrate; and
a third chemical solution supply system for supplying said third chemical solution to said third chemical treatment solution supply nozzle.

16. The system of claim 14, further comprising:
a controller coupled to said system, and configured to controllably operate said substrate table, said rinse solution supply nozzle, said first chemical treatment solution supply nozzle, and said second chemical treatment solution supply nozzle.

17. The system of claim 14, further comprising:
a developing solution supply nozzle for dispensing a developing solution onto said substrate; and
a developing solution supply system for supplying said developing solution to said developing solution supply nozzle.

18. A track system, comprising:
a coating module; and
a process module having the following:
a substrate table for supporting a rotating a substrate mounted thereon,
a rinse solution supply nozzle for dispensing a rinse solution onto said substrate,
a rinse solution supply system for supplying said rinse solution to said rinse solution supply nozzle,
a first chemical treatment solution supply nozzle for dispensing a first chemical solution onto said substrate,
a first chemical treatment solution supply system for supplying said first chemical solution to said first chemical treatment solution supply nozzle,
a second chemical treatment solution supply nozzle for dispensing a second chemical solution onto said substrate, and
a second chemical treatment solution supply system for supplying said second chemical solution to said second chemical treatment solution supply nozzle.

19. The track system of claim 18, wherein said process module further comprises:
a developing solution supply nozzle for dispensing a developing solution onto said substrate; and
a developing solution supply system for supplying said developing solution to said developing solution supply nozzle.

20. The track system of 18, further comprising:
a developing module.
